(19) United States
(12) Patent Application Publication
(10) Pub. No.: US 2025/0174443 A1
(43) Pub. Date: May 29, 2025

(54) SUBSTRATE PROCESSING APPARATUS

(71) Applicant: SAMSUNG ELECTRONICS CO., LTD., Suwon-si (KR)

(72) Inventors: Seungbin Ahn, Suwon-si (KR); Kyunghyun Kim, Suwon-si (KR); Tae-Hyun Kim, Suwon-si (KR); Sang Ki Nam, Suwon-si (KR); Kuihyun Yoon, Suwon-si (KR); Sungho Jang, Suwon-si (KR); Hyungkyu Choi, Suwon-si (KR); Jungmin Ko, Suwon-si (KR); Kwonsang Seo, Suwon-si (KR); Jungmo Yang, Suwon-si (KR); Seulgi Lee, Suwon-si (KR)

(73) Assignee: SAMSUNG ELECTRONICS CO., LTD., Suwon-si (KR)

(21) Appl. No.: 18/812,585

(22) Filed: Aug. 22, 2024

(30) Foreign Application Priority Data
Nov. 28, 2023 (KR) 10-2023-0167880

(51) Int. Cl. H01J 37/32

(52) U.S. Cl. CPC H01J 37/32834; H01J 2237/334

(57) ABSTRACT

A substrate processing apparatus includes a chamber, a support member inside the chamber and configured to support a substrate, a plasma excitation member configured to allow energy for excitation of a plasma to be applied, and a baffle provided around an outer circumference of the support member, where the baffle includes an exhaust control member having a ring structure and including an exhaust portion and a plurality of discharge holes in the exhaust portion, where a thickness of the exhaust portion is about 7 mm or less and widths of the plurality of discharge holes are about 2 mm or more.

### CROSS-REFERENCE TO RELATED APPLICATION

This application is based on and claims priority to Korean Patent Application No. 10-2023-0167880, filed on Nov. 28, 2023, in the Korean Intellectual Property Office, the disclosure of which is incorporated by reference herein in its entirety.

### BACKGROUND

Example embodiments of the disclosure relate to a substrate processing apparatus.

In order to manufacture a semiconductor device, a desired pattern is formed on a substrate through various processes such as photolithography, etching, ashing, ion implantation, thin film deposition, cleaning processes, etc. Among them, the etching process, which is a process performed to remove a selected heating region from a layer formed on a substrate, may include a wet etching process and a dry etching process.

For the dry etching, an etching device may be employed using plasma. In general, an electric field is formed in an inner space of a chamber to form the plasma. The electric field excites process gas provided in the chamber to be in a plasma state.

The plasma may refer to the state of gas ionized while including ions, electrons and radicals. The plasma is generated due to a significantly high temperature, a strong electric field, or radio frequency (RF) electromagnetic fields. The manufacturing process of a semiconductor device may include an etching process using the plasma. The etching process may be performed as ion particles, which are contained in the plasma, collide with a substrate. During processing, the substrate is heated by the plasma.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a substrate processing apparatus that may be capable of effectively discharging reaction byproducts generated during the process.

Additional aspects will be set forth in part in the description which follows and, in part, will be apparent from the description, or may be learned by practice of the presented embodiments.

According to an aspect of an example embodiment, a substrate processing apparatus may include a chamber, a support member inside the chamber and configured to support a substrate, a plasma excitation member configured to allow energy for excitation of a plasma to be applied, and a baffle provided around an outer circumference of the support member, where the baffle may include an exhaust control member having a ring structure and including an exhaust portion and a plurality of discharge holes in the exhaust portion, where a thickness of the exhaust portion is about 7 mm or less and widths of the plurality of discharge holes are about 2 mm or more.

According to an aspect of an example embodiment, a substrate processing apparatus may include a chamber, a support member inside the chamber and configured to support a substrate, a plasma excitation member configured to allow energy for excitation of a plasma to be applied, and a baffle provided around an outer circumference of the support member, where the baffle may include an exhaust control member having a ring structure and including an exhaust portion, and a plurality of discharge holes arranged along a circumferential direction of the exhaust control member, where a thickness of the exhaust portion is about 1.5 mm or more and about 7 mm or less, and widths of the plurality of discharge holes is about 2 mm or more.

According to an aspect of an example embodiment, a substrate processing apparatus may include a chamber, a support member inside the chamber and configured to support a substrate, a plasma excitation member configured to allow energy for excitation of a plasma to be applied, and a baffle provided around an outer circumference of the support member, where the baffle may include an exhaust control member having a ring structure, the exhaust control member including an exhaust portion, and a plurality of discharge holes arranged along a circumferential direction of the exhaust control member, where a thickness of the exhaust portion is about 1.5 mm or more and about 7 mm or less, widths of the plurality of discharge holes is about 2 mm or more, and an upper surface of the exhaust control member is planar.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram illustrating a substrate processing apparatus according to one or more example embodiments;

FIG. 2 is a perspective view illustrating a baffle according to one or more example embodiments;

FIG. 3 is a perspective view illustrating a baffle according to one or more example embodiments;

FIG. 4 is a plan view illustrating an exhaust control member of a baffle according to one or more example embodiments;

FIG. 5 is a plan view illustrating an exhaust control member of a baffle according to one or more example embodiments;

FIG. 6 is a cross-sectional view of a baffle according to one or more example embodiments;

FIG. 7 is a top view illustrating an exhaust control member according to one or more example embodiments;

FIG. 8 is a bottom view illustrating an exhaust control member according to one or more example embodiments;

FIG. 9 is a cross-sectional view taken along line A-A′ of FIG. 7 according to one or more example embodiments;

FIG. 10 is a cross-sectional view of an exhaust control member in a similar view of FIG. 9 according to one or more example embodiments;

FIG. 11 is a top view illustrating an exhaust control member according to one or more example embodiments;

FIG. 12 is a bottom view illustrating an exhaust control member according to one or more example embodiments;

FIG. 13 is a cross-sectional view taken along line C-C′ of FIG. 12 according to one or more example embodiments;

FIG. 14 is a cross-sectional view taken along line D-D′ of FIG. 12 according to one or more example embodiments;

FIG. 15 is a cross-sectional view taken along line E-E′ of FIG. 12 according to one or more example embodiments;

FIG. 16 is a cross-sectional view of an exhaust control member in a similar view as FIG. 14 according to one or more example embodiments;

FIG. 17 is a cross-sectional view of an exhaust control member in a similar view as FIG. 15 according to one or more example embodiments;

FIG. 18 is a diagram illustrating a substrate processing apparatus according to one or more example embodiments;

FIG. 19 is a diagram illustrating a baffle according to one or more example embodiments; and

FIG. 20 is a diagram illustrating a substrate processing apparatus according to one or more example embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

Size and thickness of each constituent element in the drawings are arbitrarily illustrated for better understanding and ease of description, the following embodiments are not limited thereto. In the drawings, the thickness of layers, films, panels, regions, etc., are exaggerated for clarity. In the drawings, the thickness of some layers and regions may be exaggerated for ease of description.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

In addition, unless explicitly described to the contrary, the word “comprise”, and variations such as “comprises” or “comprising”, will be understood to imply the inclusion of stated elements but not the exclusion of any other elements.

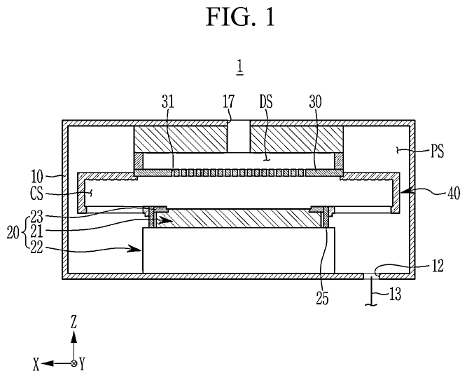

FIG. 1 is a diagram illustrating a substrate processing apparatus 1 according to one or more example embodiments.

Referring to FIG. 1, the substrate processing apparatus 1 according to one or more embodiments may include a chamber 10, a support member 20, a plasma excitation member 30, and a baffle 40.

Hereinafter, one direction on the horizontal plane may be referred to as the first direction (e.g., the X direction). The direction intersecting the first direction may be referred to as the second direction (e.g., the Y direction). The second direction may extend along on a horizontal plane. The direction intersecting the first direction and the second direction may be referred to as the third direction (e.g., the Z direction). The third direction may be referred to as a vertical direction. The vertical direction may be a vertical direction perpendicular to the horizontal plane. The horizontal plane and vertical direction may be set between components of the substrate processing apparatus 1 for better understanding and ease of description, and may not necessarily indicate the horizontal plane parallel to the ground or the direction of gravity.

The substrate processing apparatus 1 may process a substrate using plasma. For example, the substrate processing apparatus 1 may perform an etching process, a deposition process, etc., using excited plasma. The substrate may be a wafer for manufacturing semiconductor devices.

The chamber 10 may provide a process space PS in which a substrate processing process is performed. The chamber 10 may have an internal process space PS and may be provided in a sealed shape.

The chamber 10 may be made of metallic material. For example, the chamber 10 may be made of aluminum material. The chamber 10 may be grounded. A discharge hole 12 may be formed on one side of the chamber 10. The discharge hole 12 may be formed in the lower region of the chamber 10. The discharge hole 12 may be connected with an exhaust line 13. Reaction byproducts generated during the substrate processing process and gas staying in the inner space of the chamber 10 may be discharged to the outside through the discharge hole 12. The internal pressure of the chamber 10 may be reduced to specific pressure through the exhaust process.

A gas inlet 17 may be positioned on one side of the chamber 10. The gas inlet 17 may be positioned at the upper portion of the chamber 10. For example, the gas inlet 17 may be positioned in the central region of the upper surface of the chamber 10. The gas inlet 17 may be provided as a hole, a nozzle, etc., and may provide a path for process gas to flow into the inside of the chamber 10.

The support member 20 may be disposed inside the chamber 10. The support member 20 may be disposed at the lower portion of the process space PS. The support member 20 may support the substrate. The support member 20 may fix the substrate using electrostatic force.

The support member 20 may include a dielectric plate 21, a body 22, and a focus ring 23.

The dielectric plate 21 may be disposed on the upper portion of the support member 20. The dielectric plate 21 may be provided as a plate structure with a predetermined thickness. The outer circumference of the dielectric plate 21 may be circular. The outside of the dielectric plate 21 may be provided with a dielectric substance. A substrate may be placed on the upper surface of the dielectric plate 21. The area of the upper surface of the dielectric plate 21 may be smaller than the area of the substrate. The upper surface of the dielectric plate 21 may have a smaller radius than the substrate. Accordingly, when the substrate is placed on the upper surface of the dielectric plate 21, the edge region of the substrate may be positioned outside the dielectric plate 21.

An internal electrode may be disposed inside the dielectric plate 21. The internal electrode may be provided in a shape corresponding to the upper surface of the dielectric plate 21. The internal electrode may be electrically connected to the adsorption power source. The adsorption power source may include a direct current (DC) power source. Electrostatic force may be generated between the internal electrode and the substrate by the voltage applied by the adsorption power source, and the electrostatic force may cause the substrate to be adsorbed to the dielectric plate 21.

A heat transfer medium supply fluid passage may be formed inside the dielectric plate 21. The heat transfer medium supply fluid passage may be connected to the upper surface of the dielectric plate 21 and may provide a path through which heat transfer gas is supplied to the upper surface of the dielectric plate 21. The heat transfer gas may be an inert gas. For example, the heat transfer gas may be helium (He) or the like. If the heat transfer gas is supplied to the upper surface of the dielectric plate 21 while the substrate is adsorbed on the upper surface of the dielectric plate 21, the space formed between the bottom of the substrate and the dielectric plate 21 may be filled with the heat transfer gas. The heat transfer gas may serve as a medium to transfer heat from the substrate to the support member 20.

The body 22 may be disposed below the support member 20. The dielectric plate 21 may be disposed on the upper portion of the body 22. For example, the dielectric plate 21 may be attached to the body 22 by an adhesive layer. The dielectric plate 21 may be disposed above the upper central region of the body 22.

A refrigerant fluid passage may be formed inside the body 22. The refrigerant fluid passage may provide a path for the refrigerant to flow inside the body 22. For example, the refrigerant fluid passage may be formed in a spiral shape. In addition, the refrigerant fluid passage may include ring-shaped fluid passages concentrically arranged with mutually different radiuses. The refrigerant fluid passage may be configured such that ring-shaped fluid passages communicate with each other. The refrigerant may circulate through the refrigerant fluid passage and may cool the body 22. The body 22 may be cooled while cooling the dielectric plate 21 and the substrate. That is, the heat of the substrate may be transferred to the cooled body 22 through the dielectric plate 21.

At least some regions of the body 22 may be made of a metal material. For example, the body 22 may be made entirely of metal material. The body 22 may be made of aluminum material. Accordingly, the body 22 may function as an electrode. A lower power source may be electrically connected to the metal material region of the body 22. The lower power source may be provided as a high-frequency power source that generates high-frequency power. The lower power source may be provided as a radio frequency (RF) power source. Additionally, the lower power source may be omitted and the metal material region of the body 22 may be grounded.

The focus ring 23 may be disposed on an upper outer region of the support member 20. The focus ring 23 may be disposed on the outer circumference of the upper portion of the dielectric plate 21. The focus ring 23 may be disposed on the dielectric plate 21. Additionally, the focus ring 23 may be disposed on the upper edge region of the body 22. The focus ring 23 may be provided in a ring shape. The upper portion of the focus ring 23 may be stepped such that the outer portion is higher than the inner portion. The upper inner portion of the focus ring 23 may be disposed at a height corresponding to the upper surface of the dielectric plate 21. The upper inner portion of the focus ring 23 may be positioned below the edge region of the substrate. The upper outer portion of the focus ring 23 may be positioned to surround the edge region of the substrate. The focus ring 23 may improve the uniformity of density distribution of plasma. The focus ring 23 may be worn during use. As the wear of the focus ring 23 increases, the performance of controlling the density distribution of plasma may deteriorate. Accordingly, the focus ring 23 may be replaced after being used for a certain period of time or a certain number of times.

An insulating ring 25 may be disposed on at least a portion of the outer circumference of the support member 20. The insulating ring 25 may be disposed around the outer circumference of the focus ring 23. The insulating ring 25 may be made of an insulating material. For example, the insulating ring 25 may be made of quartz or the like. The insulating ring 25 may be disposed on the body 22. In addition, in the vertical direction, the inner circumference of the focus ring 23 may be disposed to correspond to the outer circumference of the body 22. In addition, the insulating ring 25 may extend downward from the outer circumference of the focus ring 23 and may be provided to surround the outer circumference of the body 22.

The plasma excitation member 30 may allow energy for excitation of plasma to be applied to the process space PS. The plasma excitation member 30 may be disposed inside the chamber 10. For example, the plasma excitation member 30 may be manufactured separately from the chamber 10 and connected to the chamber 10. Alternatively, the plasma excitation member 30 may be provided integrally with the upper structure of the chamber 10. That is, the upper structure of the chamber 10 may function as the plasma excitation member 30.

The plasma excitation member 30 may be disposed on the upper portion of the process space PS. The plasma excitation member 30 may be made of a conductive material and may be provided to have a predetermined area. The plasma excitation member 30 may be disposed to face the support member 20 in the vertical direction.

A distribution space DS may be formed in a region spaced upward from the bottom of the plasma excitation member 30. The distribution space DS may be positioned above the plasma excitation member 30. Additionally, the distribution space DS may be formed inside the plasma excitation member 30. The distribution space DS may be connected with the gas inlet 17. A distribution hole 31 may be formed in the plasma excitation member 30 to connect the distribution space DS and the lower surface of the plasma excitation member 30. Accordingly, the process gas supplied through the gas inlet 17 may be supplied downward to the plasma excitation member 30 through the distribution space DS and the distribution hole 31.

The process gas introduced into the chamber 10 may be excited into plasma by an electric field formed inside the chamber 10. Specifically, the process gas may be excited into plasma by a capacitively coupled plasma (CCP) source. The CCP source may include an upper electrode and a lower electrode. The upper electrode and the lower electrode may be arranged in a vertical direction to face each other inside the chamber 10. By applying high-frequency power to at least one of the upper electrode and the lower electrode, an electric field may be formed in the space between the upper electrode and the lower electrode, and the process gas supplied to this space may be excited in a plasma state. The upper electrode may be the plasma excitation member 30, and the lower electrode may be a metal material region of the body 22. High-frequency electric power may be applied to one of the upper and lower electrodes, and the other may be grounded. For example, the upper electrode may be grounded, and high-frequency power may be applied to the lower electrode. In contrast, high-frequency power may be applied to both the upper and lower electrodes.

The baffle 40 may divide the space positioned above the support member 20 and the space positioned below the chamber 10. The baffle 40 may control the flow rate of fluid exhausted to the outside of the chamber 10 in the space positioned above the support member 20. That is, reaction byproducts generated during the substrate processing process may flow into the discharge hole 12 via the baffle 40. The baffle 40 may be disposed around the outer circumference of the support member 20. The baffle 40 may be disposed around the outer circumference of the focus ring 23. The insulating ring 25 may be disposed between the baffle 40 and the focus ring 23, such that the baffle 40 and the focus ring 23 may be electrically insulated from each other. The baffle 40 may be grounded. The baffle 40 may have a ring structure. The center of the baffle 40 may be positioned to correspond to the center of the support member 20.

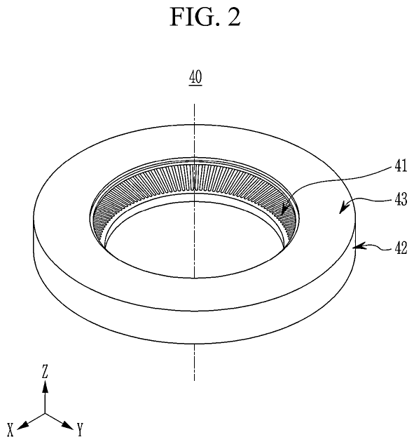

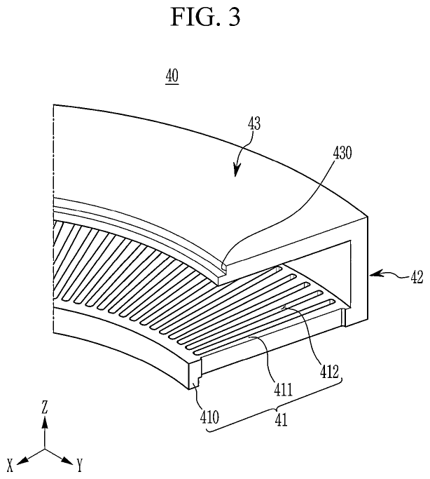

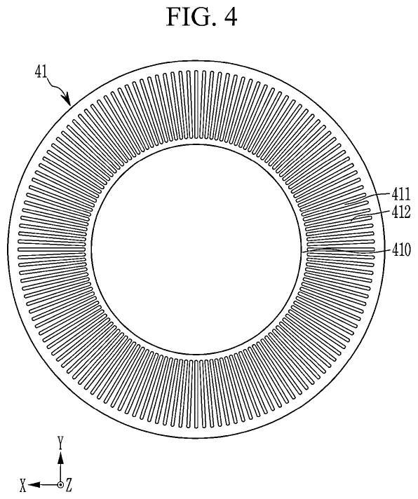

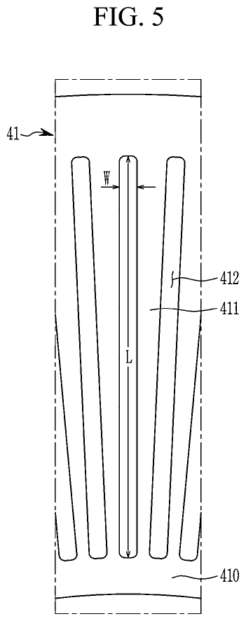

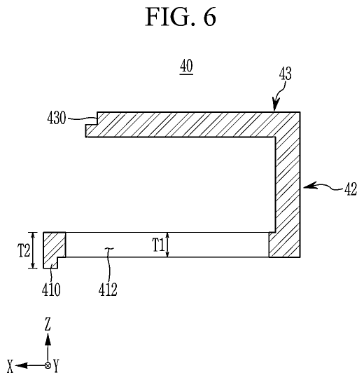

FIG. 2 is a perspective view illustrating a baffle according to one or more example embodiments. FIG. 3 is a perspective view illustrating a baffle according to one or more example embodiments. FIG. 4 is a plan view illustrating an exhaust control member of a baffle according to one or more example embodiments. FIG. 5 is a plan view illustrating an exhaust control member of a baffle according to one or more example embodiments. FIG. 6 is a cross-sectional view of a baffle according to one or more example embodiments. The baffle illustrated in FIGS. 2 to 6 may correspond to the baffle 40 of FIG. 1.

Referring to FIGS. 2 to 6, the baffle 40 may include an exhaust control member 41 and partition members 42 and 43.

The exhaust control member 41 may provide the lower structure of the baffle 40. The exhaust control member 41 may have a ring structure. The exhaust control member 41 may be disposed around the outer circumference of the support member 20. The exhaust control member 41 may be disposed around the outer circumference of the focus ring 23. The insulating ring 25 may be disposed between the exhaust control member 41 and the focus ring 23.

The exhaust control member 41 may be positioned on a horizontal plane. The center of the exhaust control member 41 may be positioned to correspond to the center of the support member 20. The center of the exhaust control member 41 may be positioned to correspond to the center of the dielectric plate 21. The center of the exhaust control member 41 may be positioned to correspond to the center of the focus ring 23. The exhaust control member 41 may have a predetermined width in the radial direction. The upper surface of the exhaust control member 41 may be provided as a plane.

The exhaust control member 41 may include a connection portion 410 and an exhaust portion 411.

The connection portion 410 may be positioned at the inner end (i.e., radially inward end) of the exhaust control member 41 facing the support member 20. The exhaust portion 411 may be positioned around outer circumference of the connection portion 410. A thickness T2 of the connection portion 410 in the vertical direction may be greater than a thickness T1 of the exhaust portion 411 in the vertical direction. The width of the exhaust portion 411 in the radial direction may be provided to be larger than the width of the connection portion 410 in the radial direction. The exhaust portion 411 may occupy most of the region of the exhaust control member 41.

A plurality of discharge holes 412 may be formed in the exhaust control member 41. The plurality of discharge holes 412 may be formed to penetrate the upper and lower surfaces of the exhaust control member 41 (i.e., the plurality of discharge holes 412 may extend through the exhaust control member 41). The plurality of discharge holes 412 may be formed in the exhaust portion 411. Each of the plurality of discharge holes 412 may have a predetermined width W. The plurality of discharge holes 412 may have a long slit shape in one direction. The width W of each of the plurality of discharge holes 412 may refer to the width W of each discharge hole 412 in the circumferential direction of the exhaust control member 41. Each discharge hole 412 may have a length L in a radial direction that is larger than the width W in the circumferential direction.

The plurality of discharge holes 412 may be arranged along the circumferential direction of the exhaust control member 41. The plurality of discharge holes 412 may have a long slit shape along the radial direction. The plurality of discharge holes 412 may have the predetermined width W along the tangential direction in the circumferential direction. The width W of each of the plurality of discharge holes 412 may be about 2 mm or more.

The exhaust portion 411 may have a predetermined thickness T1. As the exhaust portion 411 occupies most of the exhaust control member 41, the thickness T1 of the exhaust portion 411 may be referred to as the thickness T1 of the exhaust control member 41 unless otherwise specified.

When the plurality of discharge holes 412 are formed in the vertical direction, the thickness T1 of the exhaust control member 41 (i.e., the thickness T1 of the exhaust portion 411) may be understood as a height of the discharge hole 412 in the vertical direction. The thickness T1 of the exhaust control member 41 may be about 1.5 mm or more and about 7 mm or less.

Hereinafter, the plurality of discharge holes 412 may be referred to as a singular discharge hole 412. It will be understood by one of ordinary skill in the art that the description below may be applied to each of the plurality of discharge holes 412. The width W of the discharge hole 412 may be required to be adjusted to allow fluid to effectively escape through the exhaust control member 41 in the space above the support member 20. In particular, reaction byproducts generated during substrate processing process may include particulate particles. If reaction byproducts are not discharged smoothly during the substrate processing process, substrate processing efficiency decreases. Therefore, in order to smoothly discharge reaction byproducts, the width W of the discharge hole 412 may be required to be above a certain level. In order to effectively discharge reaction byproducts including particles, the width W of the discharge hole 412 may be about 2 mm or more. If the width W of the discharge hole 412 is smaller than this, particles, etc. may not be discharged smoothly, or the frequency of occurrence of the discharge hole 412 being blocked by particles may increase. This may increase the maintenance frequency of the substrate processing apparatus 1.

On the other hand, the width W of the discharge hole 412 may be required to be below a certain size to prevent the plasma excited into the upper space of the support member 20 from escaping. Specifically, the degree to which the plasma escapes through the discharge hole 412 is related to the Debye length λ_{D} defined as Equation (1) below.

$${λ}_{D} = {( \frac{{ϵ}_{0} {KT}_{e}}{{ne}^{2}} )}^{1 / 2} \qquad ( 1 )$$

In Equation (1), ∈₀ is the dielectric constant of free space, K is the Boltzmann constant, Te is the temperature of the electron, n is the density of the electron, and e is the charge of the electron.

When an electric field is applied to the plasma, the charged particles may be rearranged to block the electric field. The Debye length represents the distance from the point where the electric field is applied to the point where the electric field is offset due to the rearrangement of charged particles. Accordingly, in order for plasma to exist in a space, the width of the space may be required to be larger than the Debye length. Additionally, a sheath may be formed in the region where the plasma and the object contact each other. The thickness of the sheath may vary depending on the state of the plasma.

Accordingly, the extent to which plasma escapes through the discharge hole 412 may be affected by the width W of the discharge hole 412 and the state of the plasma, and the exhaust control member 41 may have a critical thickness t_{pinch-off}, which is the thickness that is the boundary for whether the plasma escapes through the discharge hole 412.

That is, when the thickness T1 of the exhaust control member 41 becomes smaller than the critical thickness, the plasma may escape through the discharge hole 412. The critical thickness is as shown in Equation (2) below, and it can be seen that the critical thickness varies depending on the width W of the discharge hole 412 and the state of the plasma.

$${t}_{pinch - off} = \frac{d}{π} ln [ \frac{0.135 e}{{K}_{CL} \sqrt{2} {ε}_{0}} \frac{{d}^{2} {T}_{e}^{1 / 2} {n}_{0}}{{V}^{3 / 2}} ] \qquad ( 2 )$$

In Equation (2), d is the width W of the discharge hole 412, e is the charge of the electron, Te is the temperature of the electron, n₀ is the density of the plasma, K_{CL} is a constant depending on the state of the plasma, ∈₀ is the dielectric constant of free space, and V is the voltage applied to the region where the discharge hole 412 is formed.

As the width W of the discharge hole 412 increases, the critical thickness also increases. As the critical thickness increases, the length of the discharge hole 412 increases. That is, in order to prevent plasma from escaping through the discharge hole 412, if the width W of the discharge hole 412 is increased, the length of the discharge hole 412 may also be increased. The length of the discharge hole 412 may act as a resistance to discharge reaction byproducts, etc. through the discharge hole 412. This indicates that when the width W of the discharge hole 412 exceeds a certain range, simply increasing the width W of the discharge hole 412 is not effective in effectively discharging reaction byproducts. Accordingly, the width W of the discharge hole 412 may be about 4 mm or less. More particularly, the width W of the discharge hole 412 may be about 3 mm or less.

The thickness of the above-described discharge hole 412 and the critical thickness when the electron temperature is 2 to 3 eV may be approximately 1.5 mm to 5 mm. Accordingly, when the thickness T1 of the exhaust control member 41 is about 5 mm or less, reaction byproducts may be effectively discharged through the discharge hole 412 and plasma may be prevented from escaping. Additionally, when a margin is added to the critical thickness to ensure more reliable discharge of plasma through the discharge hole 412, the thickness T1 of the exhaust control member 41 may be set to about 7 mm or less. Additionally, when low-temperature plasma is used and the width W of the discharge hole 412 is reduced, the lower limit of the thickness T1 of the exhaust control member 41 may be required to be about 1.5 mm or more. Additionally, when the width of the discharge hole 412 is approximately 2.5 mm, the lower limit of the thickness T1 of the exhaust control member 41 may be about 2.3 mm or more. In addition, when adding a margin to the critical thickness to more ensure the discharge of plasma through the discharge hole 412, the thickness T1 of the exhaust control member 41 may be about 3 mm or more.

The partition members 42 and 43 provide the upper structure of the baffle 40. The partition members 42 and 43 may be provided to surround the space positioned above the exhaust control member 41. Accordingly, the partition members 42 and 43 may partition the plasma excitation space CS from other spaces. The upper portions of the partition members 42 and 43 may be connected to the plasma excitation member 30.

The partition members 42 and 43 may be disposed on the exhaust control member 41. The partition members 42 and 43 may be formed integrally with the exhaust control member 41. Alternatively, the partition members 42 and 43 may be manufactured separately from the exhaust control member 41 and may be connected to the exhaust control member 41. The partition members 42 and 43 may be provided in a ring structure. The partition members 42 and 43 may be disposed to surround a space positioned above the support member 20, such that the plasma excitation space CS is formed inside the partition members 42 and 43. In addition, the partition members 42 and 43 may surround the space between the plasma excitation member 30 and the support member 20. The upper portions of the partition members 42 and 43 may be connected to the plasma excitation member 30. Alternatively, the upper portions of the partition members 42 and 43 may be connected to the upper portion of the chamber 10.

The partition members 42 and 43 may include a side partition 42 and an upper partition 43.

The side partition 42 may be connected to the outer end of the exhaust control member 41. The side partition 42 may have a ring structure. The side partition 42 may extend upward from the outer end of the exhaust control member 41. The side partition 42 may have a predetermined length in the vertical direction.

The upper partition 43 may be connected to the upper portion of the side partition 42. The upper partition 43 may have a ring structure. The upper partition 43 may extend from the upper portion of the side partition 42 toward the center of the baffle 40. The inner end (i.e., the radially inward end) of the upper partition 43 may be connected to the plasma excitation member 30. A connecting step 430 may be positioned at the inner end of the upper partition 43. Accordingly, the upper partition 43 may be connected to the plasma excitation member 30 in such a way that the connecting step 430 is inserted into the outer end of the plasma excitation member 30.

In some embodiments, the upper partition 43 may be omitted. The upper end of the side partition 42 may be connected to the upper portion of the chamber 10.

The process gas introduced into the chamber 10 may be excited into plasma. The plasma excitation space CS positioned inside the baffle 40 may be formed above the support member 20. The process gas introduced into the chamber 10 may be excited into plasma while positioned in the plasma excitation space CS. The process space PS inside the chamber 10 may be divided into the plasma excitation space CS and other spaces by the baffle 40. Accordingly, a higher density plasma may be excited in the region positioned above the support member 20.

Additionally, the discharge hole 412 having a predetermined width W may be formed in the exhaust control member 41. Additionally, the thickness T1 of the exhaust control member 41 may have a predetermined range corresponding to the width W of the discharge hole 412. Accordingly, reaction byproducts generated during the substrate processing process may be effectively discharged through the discharge hole 412. And, plasma may be blocked from being discharged through the discharge hole 412.

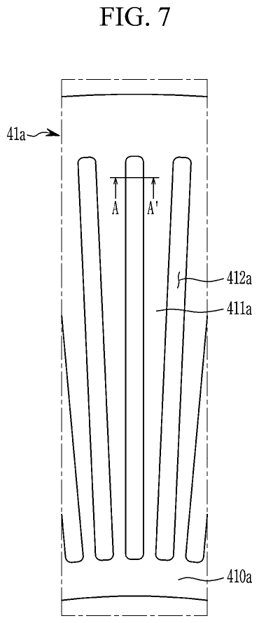

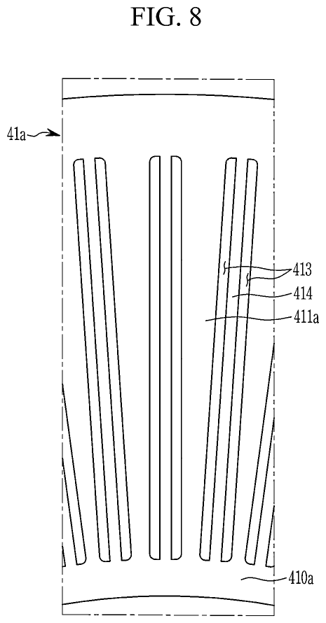

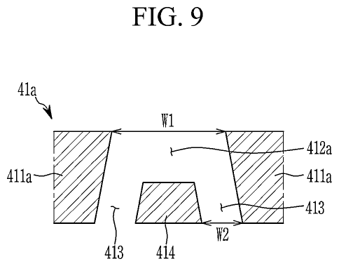

FIG. 7 is a top view illustrating an exhaust control member 41a according to one or more example embodiments. FIG. 8 is a bottom view illustrating the exhaust control member 41a of FIG. 7 according to one or more example embodiments. FIG. 9 is a cross-sectional view taken along line A-A′ of FIG. 7 according to one or more example embodiments.

Referring to FIGS. 7 to 9, the exhaust control member 41a according to one or more example embodiments will be described. In the exhaust control member 41a according to one or more embodiments, repeated descriptions of parts that are the same or similar to the exhaust control member 41, described above with reference to FIGS. 2 to 6, may be omitted.

The exhaust control member 41a may have a ring structure. The exhaust control member 41a may be disposed around the outer circumference of the support member 20. The exhaust control member 41a may be disposed around the outer circumference of the focus ring 23. The insulating ring 25 may be disposed between the exhaust control member 41a and the focus ring 23.

The exhaust control member 41a may be positioned on a horizontal plane. The center of the exhaust control member 41a may be positioned to correspond to the center of the support member 20. The center of the exhaust control member 41a may be positioned corresponding to the center of the dielectric plate 21. The center of the exhaust control member 41a may be positioned to correspond to the center of the focus ring 23. The exhaust control member 41a may have a predetermined width in the radial direction. The upper surface of the exhaust control member 41a may be provided as a plane.

The exhaust control member 41a may include a connection portion 410a and an exhaust portion 411a.

The connection portion 410a may be positioned at the inner end of the exhaust control member 41a facing the support member 20. The exhaust portion 411a may be positioned around the outer circumference of the connection portion 410a. The thickness of the connection portion 410a may be greater than the thickness of the exhaust portion 411a. The width of the exhaust portion 411a in the radial direction may be provided to be larger than the width of the connection portion 410a. The exhaust portion 411a may occupy most of the region of the exhaust control member 41a.

A plurality of discharge holes 412a and 413 may be formed in the exhaust control member 41a. The plurality of discharge holes 412a and 413 may be arranged along the circumferential direction. The plurality of discharge holes 412a and 413 may be formed to penetrate the upper and lower surfaces of the exhaust control member 41a. The plurality of discharge holes 412a and 413 may be formed in the exhaust portion 411a. The plurality of discharge holes 412a and 413 may have a long slit shape along the radial direction. That is, the plurality of discharge holes 412a and 413 may have a length in the radial direction of the exhaust control member 41a that is longer than a width in the circumferential direction of the exhaust control member 41a.

The plurality of discharge holes 412a and 413 may include an inlet 412a and a branch portion 413.

The inlet 412a may be formed at the upper portion of the exhaust portion 411a. The inlet 412a may provide upper regions of the plurality of discharge holes 412a and 413. A width W1 of the inlet 412a may be the same or similar to the width W of the plurality of discharge holes 412 described above in FIGS. 2 to 6. Additionally, the inlet 412a may have a greater width at the lower end than at the upper end.

For example, the inlet 412a may increase in width from top to bottom. In this case, the width W1 of the upper end of the inlet 412a may be the same or similar to the width W of the plurality of discharge holes 412 described above in FIGS. 2 to 6.

The branch portion 413 may be formed at the lower portion of the exhaust portion 411a. The branch portion 413 may provide a lower region of the plurality of discharge holes 412a and 413. The branch portion 413 may have a structure branched from the inlet 412a. Specifically, a shield rib 414 may be disposed in a region facing the inlet 412a in the vertical direction. Accordingly, the shield rib 414 may partially block the lower region of the inlet 412a. The shield rib 414 may be provided to extend in the radial direction. The upper end of the shield rib 414 may be disposed below the upper surface of the exhaust portion 411a. The lower end of the shield rib 414 may be disposed at a height corresponding to the lower surface of the exhaust portion 411a. Accordingly, the lower regions of the plurality of discharge holes 412a and 413 may be partitioned by the shield rib 414, such that the branch portions 413 may be positioned on both sides of the shield rib 414, respectively. The width W2 of each branch portion 413 may be smaller than the width W1 of the inlet 412a. The widths W2 of the two branch portions 413 connected to one inlet 412a may be the same or different from each other. The sum of the areas of the two branch portions 413 on the horizontal plane (in the cross-sectional view) may correspond to the area of the inlet 412a. When the width W1 of the inlet 412a is larger at the lower end than at the upper end, the sum of the areas of the two branch portions 413 on the horizontal plane may correspond to the area of the upper end of the inlet 412a.

The exhaust portion 411a may have a predetermined thickness. The thickness of the exhaust portion 411a may be the same or similar to the thickness T1 of the exhaust portion 411 described above in FIGS. 2 to 6.

The width W2 of one branch portion 413 may be smaller than the width W1 of the inlet 412a. Accordingly, the branch portion 413 more effectively blocks plasma from escaping. Specifically, sheaths may be formed inside the plurality of discharge holes 412a and 413. The sheath may be formed on the inner surface of the discharge holes 412a and 413 to a certain thickness depending on the state of the plasma. The region where the sheath is formed may serve to block the movement of plasma. A gap may occur between the sheaths formed on the inner surface of the inlet 412a.

Plasma may penetrate into the gap between the sheaths. On the other hand, the branch portion 413 may have a smaller width than the inlet 412a. Accordingly, the sheaths formed on the inner surface of the branch portion 413 may be in a form where they contact or overlap each other, thereby preventing a gap from forming between them. Accordingly, plasma may be effectively blocked from passing through the branch portion 413.

In addition, the sum of the widths W2 of the two branch portions 413 on the horizontal plane may correspond to the width W1 of the inlet 412a, such that that the flow of fluid escaping through the discharge holes 412a and 413 is formed stably. That is, the upper and lower areas of the plurality of discharge holes 412a and 413 are provided to correspond, such that the speed of the fluid flowing through the discharge holes 412a and 413 may be maintained uniformly.

Additionally, the width W1 of the inlet 412a may be provided to be the same as or similar to the width W of the plurality of discharge holes 412 described above in FIGS. 2 to 6. Accordingly, in the upper section of the plurality of discharge holes 412a and 413 where particles are introduced, the phenomenon of the plurality of discharge holes 412a and 413 being blocked by particles may be prevented.

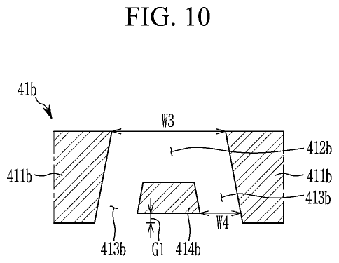

FIG. 10 is a cross-sectional view of an exhaust control member in a similar view of FIG. 9 according to one or more example embodiments. In particular, FIG. 10 is a cross-sectional view along a direction intersecting the radial direction of the region where a shield rib 414b is disposed in an exhaust control member 41b along a line similar to line A-A′ of FIG. 7, but having a different structure as is described below.

A plurality of discharge holes 412b and 413b may be formed in the exhaust control member 41b. The plurality of discharge holes 412b and 413b may be arranged along the circumferential direction. The plurality of discharge holes 412b and 413b may be formed to penetrate through the upper and lower surfaces of the exhaust control member 41b. The plurality of discharge holes 412b and 413b may be formed in an exhaust portion 411b. The plurality of discharge holes 412b and 413b may have a long slit shape along the radial direction. That is, the plurality of discharge holes 412a and 413 may have a length in the radial direction of the exhaust control member 41b that is longer than a width in the circumferential direction of the exhaust control member 41b.

The plurality of discharge holes 412b and 413b may include the inlet 412b and the branch portion 413b.

The inlet 412b may be formed at the upper portion of the exhaust portion 411b. The inlet 412b may correspond to an upper region of the discharge holes 412b and 413b. A width W3 of the inlet 412b may be the same or similar to the width W of the discharge hole 412 described above in FIGS. 2 to 6. Additionally, the inlet 412b may have a greater width at the lower end than at the upper end. For example, the inlet 412b may increase in width from top to bottom. In this case, the width W3 of the upper end of the inlet 412b may be the same or similar to the width W of the discharge hole 412 described above in FIGS. 2 to 6.

The branch portion 413b may be disposed in the region between the lower end of the inlet 412b and the lower ends of the plurality of discharge holes 412b and 413b. The branch portion 413b may have a structure branched from the inlet portion 412b. Specifically, the shield rib 414b may be disposed in a region facing the inlet 412b in the vertical direction. Accordingly, the shield rib 414b may partially block the lower region of the inlet 412b. The shield rib 414b may be provided to extend in the radial direction. The upper end of the shield rib 414b may be positioned lower than the upper surface of the exhaust portion 411a. The lower end of the shield rib 414b may be positioned above the lower surface of the exhaust portion 411b. That is, the lower end of the shield rib 414b may be positioned above the lower surface of the exhaust portion 411b by a separation gap G1. Accordingly, the plurality of discharge holes 412b and 413b may be partitioned by the shield rib 414b in some sections according to the vertical direction, and the branching portions 413b may be positioned on both sides of the shield rib 414b.

A width W4 of the branch portion 413b may be smaller than the width W3 of the inlet 412b. The widths W4 of the two branch portions 413b branched from one inlet 412b may be the same or different from each other. The sum of the widths of the two branch portions 413b on the horizontal plane (i.e., in the cross-sectional views) may correspond to the width of the inlet 412b. When the width W3 of the inlet 412b is larger at the lower end than at the upper end, the sum of the widths of the two branch portions 413b on the horizontal plane may correspond to the width of the upper end of the inlet 412b.

Since the remaining parts of the exhaust control member 41b may be the same or similar exhaust control members described above, repeated descriptions may be omitted.

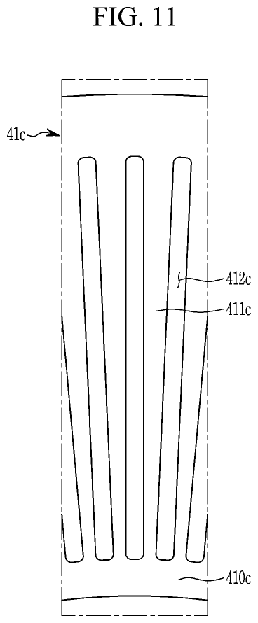

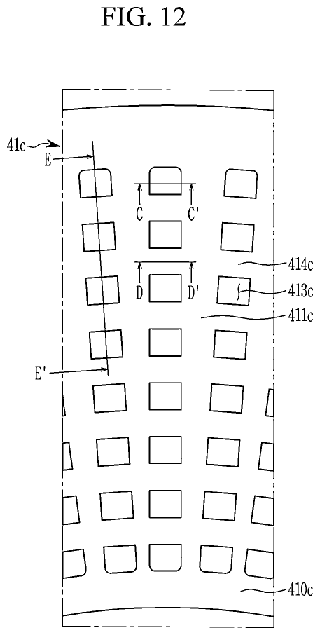

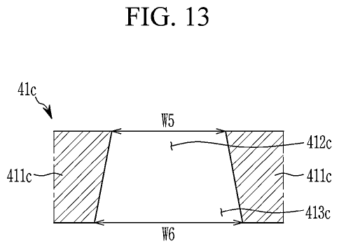

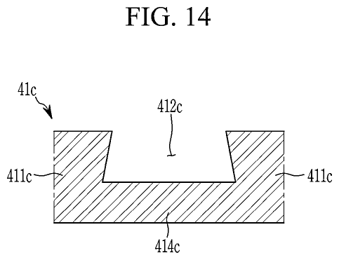

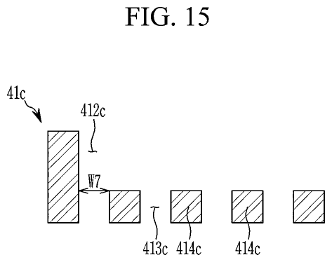

FIG. 11 is a top view illustrating an exhaust control member 41c according to one or more example embodiments. FIG. 12 is a bottom view illustrating the exhaust control member 41c according to one or more example embodiments. FIG. 13 is a cross-sectional view taken along line C-C′ of FIG. 12 according to one or more example embodiments. FIG. 14 is a cross-sectional view taken along line D-D′ of FIG. 12 according to one or more example embodiments. FIG. 15 is a cross-sectional view taken along line E-E′ of FIG. 12 according to one or more example embodiments.

Referring to FIGS. 11 to 15, the exhaust control member 41c according to one or more example embodiments will be described.

The exhaust control member 41c may include a connection portion 410c and an exhaust portion 411c.

The connection portion 410c may be positioned at the inner end (i.e., a radially inward end) of the exhaust control member 41c facing the support member 20. The exhaust portion 411c may be positioned around the outer circumference of the connection portion 410c. The thickness of the connection portion 410c may be greater than the thickness of the exhaust portion 411c. The width of the exhaust portion 411c in the radial direction may be larger than the width of the connection portion 410c. The exhaust portion 411c may occupy most of the region of the exhaust control member 41c. The upper surface of the exhaust control member 41c may be provided as a plane.

A plurality of discharge holes 412c and 413c may be formed in the exhaust control member 41c. The plurality of discharge holes 412c and 413c may be arranged along the circumferential direction. The plurality of discharge holes 412c and 413c may be formed to penetrate through the upper and lower surfaces of the exhaust control member 41c. The plurality of discharge holes 412c and 413c may be formed in the exhaust portion 411c. The plurality of discharge holes 412c and 413c may have a long slit shape along the radial direction (i.e., the length of the plurality of discharge holes in the radial direction of the exhaust control member 41c may be greater than the width of the plurality of discharge holes in the circumferential direction of the exhaust control member 41c).

The plurality of discharge holes 412c and 413c may include an inlet 412c and a branch portion 413c.

The inlet 412c may be formed at the upper portion of the exhaust portion 411c. The inlet 412c may provide an upper region of the plurality of discharge holes 412c and 413c. A width W5 of the inlet 412c may be the same or similar to the width W of the discharge hole 412 described above in FIGS. 2 to 6. Additionally, the inlet 412c may have a greater width at the lower end than at the upper end. For example, the inlet 412c may increase in width from top to bottom. In this case, the width W5 of the upper end of the inlet 412c may be the same or similar to the width W of the discharge hole 412 described above in FIGS. 2 to 6.

The branch portion 413c may be formed at the lower portion of the exhaust portion 411c. The branch portion 413c may provide a lower region of the discharge holes 412c and 413c. The branch portion 413c may have a structure branched from the inlet 412c. Specifically, the shield rib 414c may be positioned in a region facing the inlet 412c in the vertical direction. The upper end of the shield rib 414c may be positioned lower than the upper surface of the exhaust portion 411c. The lower end of the shield rib 414c may be positioned at a height corresponding to the lower surface of the exhaust portion 411c.

The shield rib 414c may be disposed in a direction intersecting the radial direction. For example, the shield rib 414c may be disposed in a tangential direction to the circumferential direction. A plurality of shield ribs 414c may be provided in one discharge hole 412c and 413c. The plurality of shield ribs 414c may be disposed to be spaced apart along the radial direction. The distance between adjacent shield ribs 414c may be the same or different.

Accordingly, the lower regions of the discharge holes 412c and 413c may be partitioned by the shield rib 414c, such that a plurality of branch portions 413c may be positioned along the radial direction.

The branch portion 413c may have a predetermined width W6 along the tangential direction in the circumferential direction. The branch portion 413c may have a predetermined length W7 along the radial direction. The width W6 of the lower end of the branch portion 413c may be larger than the width W5 of the upper end of the inlet 412c. The length W7 of the branch portion 413c may be smaller than the width W5 of the inlet 412c. When the width W5 of the inlet 412c is different for each region, the length W7 of the branch portion 413c may be smaller than the width W5 of the upper end of the inlet 412c. The sum of the widths of the plurality of branch portions 413c on the horizontal plane may correspond to the width of the inlet 412c. When the width W5 of the inlet 412c is larger at the lower end than at the upper end, the sum of the widths of the plurality of branch portions 413c on the horizontal plane may correspond to the width of the upper end of the inlet 412c. When the width W6 of the branch portion 413c is different for each region, the sum of the widths of the plurality of branch portions 413c on the horizontal plane may correspond to the width of the inlet 412c, based on the section with the smallest width in the branch portion 413c. When the width W5 of the inlet 412c and the width W6 of the branch portion 413c are different for each region, the sum of the widths of the plurality of branch portions 413c on the horizontal plane may correspond to the width of the inlet 412c, based on the section with the smallest width in the inlet 412c and the section with the smallest width in the branch portion 413c.

The length W7 of the branch portion 413c in the radial direction may be smaller than the width W5 of the inlet 412c. Accordingly, the sheaths formed on the inner surface of the branch portion 413c in the radial direction may be in a form where they contact or overlap each other, thereby preventing a gap from forming therebetween. Accordingly, plasma may be effectively blocked from passing through the branch portion 413c.

Since the remaining parts of the exhaust control member 41c are the same or similar to those of the exhaust control members described above, repeated descriptions may be omitted.

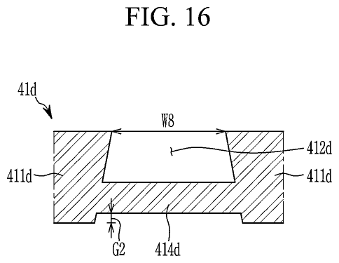

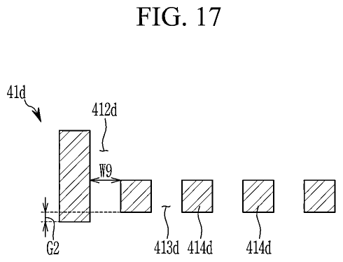

FIG. 16 is a cross-sectional view of an exhaust control member in a similar view as FIG. 14 according to one or more example embodiments. FIG. 17 is a cross-sectional view of an exhaust control member in a similar view as FIG. 15 according to one or more example embodiments. That is, FIGS. 16 and 17 respectively show similar views as FIGS. 14 and 15 where a shield rib 414d is disposed instead of shield rib 414b, according to one or more example embodiments.

Referring to FIGS. 16 and 17, the exhaust control member 41d according to one or more example embodiments will be described.

A plurality of discharge holes 412d and 413d may be formed in the exhaust control member 41d. The plurality of discharge holes 412d and 413d may be arranged along the circumferential direction. The plurality of discharge holes 412d and 413d may be formed to penetrate through the upper and lower surfaces of the exhaust control member 41d. The plurality of discharge holes 412d and 413d may be formed in the exhaust portion 411c. The plurality of discharge holes 412d and 413d may have a long slit shape along the radial direction.

The discharge holes 412d and 413d may include an inlet 412d and a branch portion 413d.

The inlet 412d may be formed at the upper portion of the exhaust portion 411c. The inlet 412d may provide an upper region of the discharge holes 412d and 413d. A width W8 of the inlet 412d may be the same or similar to the width W of the discharge hole 412 described above in FIGS. 2 to 6. Additionally, the inlet 412d may have a greater width at the lower end than at the upper end. For example, the inlet 412d may increase in width from top to bottom. In this case, the width W8 of the upper end of the inlet 412d may be the same or similar to the width W of the discharge hole 412 described above in FIGS. 2 to 6.

The branch portion 413d may be formed in a region between the lower end of the inlet 412d and the lower ends of the plurality of discharge holes 412d and 413d. The branch portion 413d may have a structure branched from the inlet 412d. Specifically, the shield rib 414d may be positioned in a region facing the inlet 412d in the vertical direction. The upper end of the shield rib 414d may be positioned lower than the upper surface of the exhaust portion 411d. The lower end of the shield rib 414d may be positioned above the lower surface of the exhaust portion 411d. That is, the lower end of the shield rib 414d is positioned above the lower surface of the exhaust portion 411d by a separation gap G2.

The shield rib 414d may be disposed in a direction intersecting the radial direction. For example, the shield rib 414d may be disposed in a tangential direction to the circumferential direction. A plurality of shield ribs 414d may be provided in one discharge hole 412d and 413d. A plurality of shield ribs 414d may be disposed to be spaced apart along the radial direction. The distance between adjacent shield ribs 414d may be the same or different.

Accordingly, the plurality of discharge holes 412d and 413d may be partitioned by the shield rib 414d in some sections according to the vertical direction, and a plurality of branch portions 413d may be positioned along the radial direction.

The branch portion 413d may have a predetermined length W9 along the radial direction. The length W9 of the branch portion 413d may be smaller than the width W8 of the inlet 412d. When the width W8 of the inlet 412d is different for each region, the length W9 of the branch portion 413d may be smaller than the width W8 of the upper end of the inlet 412d. The sum of the widths of the plurality of branch portions 413d on the horizontal plane may correspond to the width of the inlet 412d. When the width W8 of the inlet 412d is larger at the lower end than at the upper end, the sum of the widths of the plurality of branch portions 413d on the horizontal plane may correspond to the width of the upper end of the inlet 412d. When the width of the branch portion 413d is different for each region, the sum of the widths of the plurality of branch portions 413d on the horizontal plane may correspond to the width of the inlet 412d, based on the section with the smallest width in the branch portion 413d. When the width W8 of the inlet 412d and the width of the branch portion 413d is different for each region, the sum of the widths of the plurality of branch portions 413d on the horizontal plane may correspond to the width of the inlet 412d, based on the section with the smallest width in the inlet 412d and the section with the smallest width in the branch portion 413d.

The length W9 of the branch portion 413d in the radial direction may be smaller than the width W8 of the upper end of the inlet 412d. Accordingly, the sheaths formed on the inner surface of the branch portion 413d in the radial direction may be in a form where they contact or overlap each other, thereby preventing a gap from forming therebetween. Accordingly, plasma may be effectively blocked from passing through the branch portion 413d.

Since the remaining parts of the exhaust control member 41d are the same or similar to those of the exhaust control members described above, repeated descriptions may be omitted.

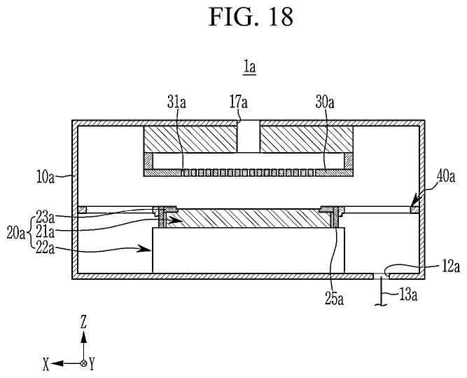

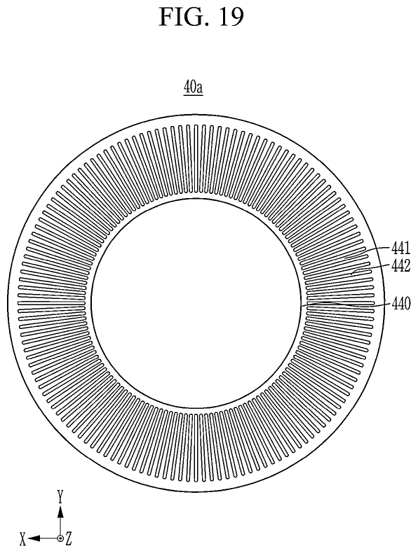

FIG. 18 is a diagram illustrating a substrate processing apparatus 1a according to one or more example embodiments. FIG. 19 is a diagram illustrating a baffle 40a according to one or more example embodiments.

Referring to FIGS. 18 and 19, the substrate processing apparatus 1a according to one or more embodiments may include a chamber 10a, a support member 20a, a plasma excitation member 30a, and a baffle 40a.

The chamber 10a may provide a process space inside where a substrate processing process is performed. A discharge hole 12a may be formed on one side of the chamber 10a. The discharge hole 12a may be formed in the lower region of the chamber 10a. The discharge hole 12a may be connected to an exhaust line 13a. A gas inlet 17a may be positioned on one side of the chamber 10a.

The support member 20a may be disposed inside the chamber 10a. The support member 20a may support the substrate.

The support member 20a may include a dielectric plate 21a, a body 22a, and a focus ring 23a.

An insulating ring 25a may be disposed on at least a portion of the outer circumference of the support member 20a.

The plasma excitation member 30a may allow energy for excitation of plasma to be applied to the process space. The plasma excitation member 30a may be disposed inside the chamber 10a.

A distribution hole 31a may be formed in the plasma excitation member 30a to supply the gas introduced into the gas inlet 17a.

The specific configuration of the chamber 10a, the support member 20a, and the plasma excitation member 30a may be the same or similar to the chamber 10, the support member 20, and the plasma excitation member 30 of FIG. 1, and the repeated description thereof may be omitted.

The baffle 40a may divide the space positioned above the support member 20a and the space positioned below the chamber 10a. The baffle 40a may be disposed around the outer circumference of the support member 20a. The baffle 40a may be disposed around the outer circumference of the focus ring 23a. The insulating ring 25a may be disposed between the baffle 40a and the focus ring 23a, such that the baffle 40a and the focus ring 23a may be electrically insulated from each other. The baffle 40a may be grounded. The baffle 40a may have a ring structure. The center of the baffle 40a may be positioned to correspond to the center of the support member 20a. The outer region of the baffle 40a may be positioned adjacent to the chamber 10a. For example, the outer region of the baffle 40a may be disposed to contact the chamber 10a. Additionally, the outer region of the baffle 40a and the chamber 10a may be provided to contact each other through a liner or the like.

The baffle 40a may include a connection portion 440 and an exhaust portion 441. A discharge hole 442 may be formed in the baffle 40a. Discharge holes 442 may be formed to penetrate through the upper and lower surfaces of the baffle 40a. The discharge hole 442 may be formed in the exhaust portion 441.

The baffle 40a may have the same or similar structure as the exhaust control member 41 described above in FIGS. 2 to 6, and repeated description thereof may be omitted.

Additionally, the baffle 40a may have the same or similar structure as the exhaust control member 41a described above in FIGS. 7 to 9, and repeated description thereof may be omitted.

Additionally, the baffle 40a may have the same or similar structure as the exhaust control member 41b described above in FIG. 10, and repeated description thereof may be omitted.

Additionally, the baffle 40a may have the same or similar structure as the exhaust control member 41c described above in FIGS. 11 to 15, and repeated description thereof may be omitted.

Additionally, the baffle 40a may have the same or similar structure as the exhaust control member 41d described above in FIGS. 16 and 17, and repeated description thereof may be omitted.

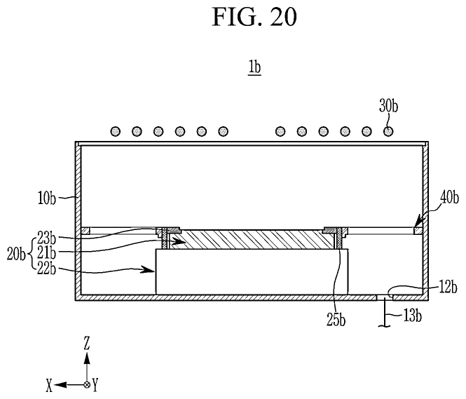

FIG. 20 is a diagram illustrating a substrate processing apparatus 1b according to one or more example embodiments.

Referring to FIG. 20, the substrate processing apparatus 1b according to one or more embodiments may include a chamber 10b, a support member 20b, a plasma excitation member 30b, and a baffle 40b.

The chamber 10b may provide a process space inside where a substrate processing process is performed. A discharge hole 12b may be formed on one side of the chamber 10b. The discharge hole 12b may be formed in the lower region of the chamber 10b. The discharge hole 12b may be connected to an exhaust line 13b. At least a portion of the upper surface of the chamber 10b may be provided with a dielectric substance.

The support member 20b may be disposed inside the chamber 10b. The support member 20b may support the substrate.

The support member 20b may include a dielectric plate 21b, a body 22b, and a focus ring 23b. The support member 20b may be the same or similar to the support member 20 of FIG. 1, and therefore repeated descriptions may be omitted.

The plasma excitation member 30b may allow energy for excitation of plasma to be applied to the process space. The plasma excitation member 30b may be disposed outside the chamber 10b. The plasma excitation member 30b may be provided as an antenna structure. Accordingly, the plasma excitation member 30b may generate electromagnetic waves for plasma excitation through power provided by the RF power source. The plasma excitation member 30b may be disposed adjacent to the upper surface of the chamber 10b. The plasma excitation member 30b may be disposed to face the upper surface of the chamber 10b in the vertical direction.

The baffle 40b may divide the space positioned above the support member 20b and the space positioned below the chamber 10b. The baffle 40b may control the flow rate of fluid exhausted to the outside of the chamber 10b in the space positioned above the support member 20b. That is, reaction byproducts generated during the substrate processing process may flow into the discharge hole 12b via the baffle 40b. The baffle 40b may be disposed around the outer circumference of the support member 20b. The baffle 40b may be disposed around the outer circumference of the focus ring 23b. The insulating ring 25b may be disposed between the baffle 40b and the focus ring 23b, such that the baffle 40b and the focus ring 23b may be electrically insulated from each other. The baffle 40b may be grounded. The baffle 40b may have a ring structure. The center of the baffle 40b may be positioned to correspond to the center of the support member 20b.

The baffle 40b may have the same or similar structure as the baffle 40 described above in FIGS. 2 to 16, and repeated description thereof may be omitted.

Additionally, the baffle 40b may include an exhaust control member having the same or similar structure as the exhaust control member 41a described above in FIGS. 7 to 9, and repeated description thereof may be omitted.

Additionally, the baffle 40b may include an exhaust control member having the same or similar structure as the exhaust control member 41b described above in FIG. 10, and repeated description thereof may be omitted.

Additionally, the baffle 40b may include an exhaust control member having the same or similar structure as the exhaust control member 41c described above in FIGS. 11 to 15, and repeated description thereof may be omitted.

Additionally, the baffle 40b may include an exhaust control member having the same or similar structure as the exhaust control member 41d described above in FIGS. 16 and 17, and repeated description thereof may be omitted.

Additionally, the baffle 40b may have the same or similar structure as the baffle 40a described above in FIG. 19, and repeated description thereof may be omitted.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims. cm What is claimed is:

1. A substrate processing apparatus, comprising:
a chamber;
a support member inside the chamber and configured to support a substrate;
a plasma excitation member configured to allow energy for excitation of a plasma to be applied; and
a baffle provided around an outer circumference of the support member,
wherein the baffle comprises:
an exhaust control member having a ring structure and comprising:
an exhaust portion; and
a plurality of discharge holes in the exhaust portion,
wherein a thickness of the exhaust portion is about 7 mm or less, and
wherein widths of the plurality of discharge holes are about 2 mm or more.

2. The substrate processing apparatus of claim 1, wherein the thickness of the exhaust portion is about 5 mm or less.

3. The substrate processing apparatus of claim 1, wherein the thickness of the exhaust portion is about 1.5 mm or more.

4. The substrate processing apparatus of claim 1, wherein the thickness of the exhaust portion is about 2.3 mm or more.

5. The substrate processing apparatus of claim 1, wherein each of the plurality of discharge holes comprises:
an inlet positioned in an upper region of a respective discharge hole; and
a branch portion branched from the inlet.

6. The substrate processing apparatus of claim 5, wherein the baffle further comprises:
a shield rib facing the inlet in a vertical direction and configured to at least partially block a lower region of the inlet,
wherein the branch portion comprises a first branch portion positioned on a first side of the shield rib and a second branch portion positioned on a second side of the shield rib.

7. The substrate processing apparatus of claim 6, wherein the shield rib extends in a radial direction of the exhaust control member.

8. The substrate processing apparatus of claim 5, wherein a width of the branch portion is smaller than the width of the inlet.

9. The substrate processing apparatus of claim 5, wherein the baffle further comprises:
a shield rib facing the inlet in a vertical direction, the shield rib configured to at least partially block a lower region of the inlet,
wherein the shield rib is provided in a direction intersecting a radial direction of the exhaust control member.

10. The substrate processing apparatus of claim 5, wherein the baffle further comprises a plurality of shield ribs in one of the plurality of discharge holes and spaced apart along a radial direction of the exhaust control member.

11. The substrate processing apparatus of claim 5, wherein the baffle further comprises a shield rib,
wherein the branch portion comprises a first branch portion and a second branch portion divided by the shield rib.

12. The substrate processing apparatus of claim 11, wherein a length of the branch portion in a radial direction of the exhaust control member is smaller than a width of the inlet.

13. The substrate processing apparatus of claim 1, wherein an upper surface of the exhaust control member is planar.

14. The substrate processing apparatus of claim 1, wherein the baffle further comprises:
a partition member on the exhaust control member, the partition member having a ring structure.

15. A substrate processing apparatus, comprising:
a chamber;
a support member inside the chamber and configured to support a substrate;
a plasma excitation member configured to allow energy for excitation of a plasma to be applied; and
a baffle provided around an outer circumference of the support member,
wherein the baffle comprises:
an exhaust control member having a ring structure and comprising:
an exhaust portion; and
a plurality of discharge holes arranged along a circumferential direction of the exhaust control member,
wherein a thickness of the exhaust portion is about 1.5 mm or more and about 7 mm or less,
wherein widths of the plurality of discharge holes is about 2 mm or more.

16. The substrate processing apparatus of claim 15, wherein each of the plurality of discharge holes comprises:
an inlet in an upper region of a respective discharge hole; and
a branch portion branched from the inlet.

17. The substrate processing apparatus of claim 16, wherein the baffle further comprises:
a shield rib facing the inlet in a vertical direction and extending in a radial direction of the exhaust control member, the shield rib configured to at least partially block a lower region of the inlet,
wherein the branch portion comprises a first branch portion positioned on a first side of the shield rib and a second branch portion positioned on a second side of the shield rib.

18. The substrate processing apparatus of claim 16, wherein the baffle further comprises:
a plurality of shield ribs facing the inlet in a vertical direction and provided in a direction intersecting a radial direction of the exhaust control member, the plurality of shield ribs configured to at least partially block a lower region of the inlet, and provided in a direction intersecting the radial direction,
wherein the branch portion comprises a first branch portion and a second branch portion divided by at least one shield rib of the plurality of shield ribs.

19. A substrate processing apparatus, comprising:
a chamber;
a support member inside the chamber and configured to support a substrate;
a plasma excitation member configured to allow energy for excitation of a plasma to be applied; and
a baffle provided around an outer circumference of the support member,
wherein the baffle comprises:
an exhaust control member having a ring structure, the exhaust control member comprising:
an exhaust portion; and
a plurality of discharge holes arranged along a circumferential direction of the exhaust control member,
wherein a thickness of the exhaust portion is about 1.5 mm or more and about 7 mm or less,
wherein widths of the plurality of discharge holes is about 2 mm or more, and
where an upper surface of the exhaust control member is planar.

20. The substrate processing apparatus of claim 19, wherein each of the plurality of discharge holes comprises:
an inlet in an upper region of a respective discharge hole; and
a branch portion branched from the inlet.
